(19) United States
(12) Patent Application Publication
(10) Pub. No.: US 2025/0361138 A1
(43) Pub. Date: Nov. 27, 2025

(54) ELECTROMECHANICAL SYSTEM COMPRISING A MOVABLE ELEMENT PROVIDED WITH AN OPENING

(71) Applicant: COMMISSARIAT À L’ENERGIE ATOMIQUE ET AUX ENERGIES ALTERNATIVES, PARIS (FR)

(72) Inventor: Loïc JOET, GRENOBLE CEDEX 9 (FR)

(21) Appl. No.: 19/218,987

(22) Filed: May 27, 2025

(30) Foreign Application Priority Data
May 27, 2024 (FR) FR2405415

(51) Int. Cl. B81B 3/00; B81C 1/00

(52) U.S. Cl. CPC B81B 3/0051; B81C 1/00198; B81B 2201/0257; B81B 2201/0264; B81B 2203/0127; B81B 2203/0154; B81B 2203/0315; B81B 2203/0361; B81B 2203/04; B81C 2201/013

(57) ABSTRACT

An electromechanical system includes a frame; an element movable relative to the frame, the movable element comprising a membrane and a rigidifying structure for the membrane; a capacitive measurement or actuation device; a first transmission device for a movement between the movable element and the capacitive measurement or actuation device, the first transmission device being rotatably movable relative to the frame by a plurality of first pivot hinges; in which system: a first opening is arranged in the movable element; the frame includes a first island extending into the first opening; and the first transmission device is connected to the first island via one of the first pivot hinges.

### CROSS-REFERENCE TO RELATED APPLICATIONS

This application claims priority to French Patent Application No. 2405415, filed May 27, 2024, the entire content of which is incorporated herein by reference in its entirety.

### FIELD

The technical field of the invention is that of electromechanical systems, especially of the MicroElectroMechanical Systems (MEMS) or NanoElectroMechanical Systems (NEMS) type. The invention relates more particularly to an electromechanical system comprising a movable element, capacitive measurement or actuation means and a movement transmission device for a movement between the movable element and the capacitive measurement or actuation means. Such a system can be used as an electroacoustic transducer (e.g. microphone, loudspeaker, etc.) or as a differential pressure sensor.

### BACKGROUND

Microelectromechanical or nanoelectromechanical microphones represent a rapidly expanding market, especially thanks to the development of nomadic apparatuses such as tablets, smartphones and other connected objects, in which they are gradually replacing electret microphones.

Microphones measure a rapid variation in atmospheric pressure, also known as acoustic pressure. They therefore include at least one part in contact with the external environment.

Most MEMS or NEMS microphones manufactured today are capacitive detection microphones. FIG. 1 represents an example of a capacitive detection microphones 1, described in patent FR3114584B1.

The microphone 1 comprises a frame (not represented) at least partly delimiting a first zone 11 and a second zone 12, an element 13 movable relative to the frame and a movement transmission device 14 for a movement between the first zone 11 and the second zone 12. The first and second zones 11-12 of the microphone 1 are sealingly isolated from each other.

The movable element 13, also referred to as a piston, is in contact with the first zone 11. It comprises a membrane 131 and a rigidifying structure 132 for the membrane. The role of the membrane 131 of the piston 13 is to collect, over its entire surface, a pressure difference between its two faces, in order to deduce a variation in atmospheric pressure. One face of the membrane 131 is subjected to atmospheric pressure (the variation of which is desired to be detected) and an opposite face of the membrane 131 is subjected to a reference pressure.

In addition, the microphone 1 comprises capacitive detector 15 disposed in the second zone 12. The capacitive detector 15 makes it possible to measure displacement of the piston 13, and therefore the difference in pressure between its two faces. They comprise a movable electrode 151 and at least one fixed electrode facing the movable electrode 151. The electrodes form the plates of a capacitor whose capacitance varies as a function of the displacement of the piston 13.

The transmission device 14 is rotatably movably mounted relative to the frame by several pivot hinges 16. The transmission device 14 comprises two first transmission arms 141 extending through the first zone 11, two second transmission arms 142 extending through the second zone 12 and two transmission shafts 143 extending partly through the first zone 11 and partly through the second zone 12. Each transmission shaft 143 connects a first transmission arm 141 to a second transmission arm 142.

Each first transmission arm 141 comprises a first end coupled to the piston 13 and a second opposite end coupled to the transmission shaft 143 associated therewith. Each second transmission arm 142 comprises a first end coupled to the movable electrode 151 of the capacitive detector 15 and a second, opposite to the first, end coupled to the transmission shaft 143 associated therewith.

Patent FR3059659B1 describes a capacitive detection microphones similar to that of FIG. 1. The capacitive detector comprises a movable electrode and two fixed electrodes between which the movable electrode is disposed. The electrodes form the plates of two capacitors whose capacitances vary in opposite senses as a function of the displacement of the piston. The measurement of piston displacement is therefore a differential measurement.

For this type of differential measurement, the capacitors are first charged by applying a DC bias voltage between the movable electrode and the fixed electrodes via a high resistance. The displacement of the piston results in a variation in the capacitances, and therefore a variation in the voltage between the fixed electrodes (the charge of the capacitor being substantially constant at audible frequencies, typically above 100 Hz) which can be read by an instrumentation amplifier.

These capacitive detection microphones can fail due to a so-called “pull-in” phenomenon of the movable electrode which is common to all electromechanical systems comprising capacitive measurement or actuation device. This pull-in phenomenon is caused by the electrostatic force, which tends to bring the movable electrode closer to the fixed electrode (or to one of the fixed electrodes) and which depends on the square of the bias voltage. The electrostatic force, which also depends on the displacement of the movable electrode, can be approximated to first order by a constant force plus the force exerted by a spring of negative spring constant for small displacements.

To avoid this pull-in phenomenon (up to a certain point), an elastic force is opposed to the electrostatic force. This elastic force can be generated by springs connecting the frame of the movable electrode 151 to the frame of the microphone 1. The greater the spring constant of the springs, the greater the voltage value at which the electrostatic force exceeds the elastic force (so-called “pull-in voltage”) and the higher the voltage at which the movable electrode 151 can be biased. This is advantageous because the sensitivity of the microphone 1 increases with the bias voltage.

A drawback of the capacitive detection microphones described above is that energy is lost in the deformation of the piston 13, the transmission device 14 and the frame of the movable electrode 151, which accounts for a loss of useful signal when detecting dynamic variations in pressure. One solution for reducing these energy losses, and therefore increasing sensitivity of the microphone, would be to reinforce the rigidifying structure 132 for the piston 13, the transmission device 14 and the frame of the movable electrode 151. However, this solution would considerably increase mass of these movable parts, reducing the resonant frequency of the microphone.

### SUMMARY

There is therefore a need to provide an electromechanical system with capacitive detection or capacitive actuation which offers better performance, especially in terms of sensitivity and resonant frequency.

According to an aspect of the invention, this need aims to be satisfied by providing an electromechanical system comprising:
a frame;
an element movable relative to the frame, the movable element comprising a membrane and a rigidifying structure for the membrane;
a capacitive measurement or actuation device; and
a first movement transmission device for a movement between the movable element and the capacitive measurement or actuation device, the first transmission device being rotatably movable relative to the frame by a plurality of first pivot hinges.

This electromechanical system is remarkable in that:
a first opening is arranged in the movable element;
the frame comprises a first island extending into the first opening; and
the first transmission device is connected to the first island via one of the first pivot hinges.

In an embodiment, a portion of the first island forms a stop for limiting displacement of the movable element. The stop is in an embodiment formed by a peripheral portion of the first island.

The rigidifying structure for the movable element may comprise two fingers, and the first island may comprise a finger configured to bear against the membrane of the movable element between the two fingers of the rigidifying structure.

The first transmission device may comprise:
a first transmission shaft having a first longitudinal axis of rotation;
at least one first transmission arm comprising a first end coupled to the movable element and a second end integral with the first transmission shaft.

In an embodiment, the first transmission shaft comprises a first portion extending to the capacitive measurement or actuation device and a second portion connected to the first island, the first and second portions of the first transmission shaft being separate.

According to a first development of this embodiment, the system comprises a first hinge between the movable element and the first transmission device, and the first transmission device comprises two first transmission arms converging towards the first hinge, one of the two first transmission arms extending from the first portion of the first transmission shaft and the other of the two first transmission arms extending from the second portion of the first transmission shaft.

According to a second development compatible with the first one:
the first transmission shaft is located on a first side of the membrane of the movable element;
the rigidifying structure for the movable element comprises a first beam located on the first side of the membrane; and the first and second portions of the first transmission shaft are separated by the first beam.

Advantageously, the first beam extends in a direction perpendicular to the first longitudinal axis of rotation and has a length greater than or equal to 50% of the dimension of the movable element measured in said direction.

The rigidifying structure for the movable element may comprise two first beams located on the first side of the membrane and extending in parallel to each other and the second portion of the first transmission shaft may be located between the two first beams.

The rigidifying structure for the movable element may further comprise a second beam located on a second opposite side of the membrane and superimposed on the first beam.

The rigidifying structure for the movable element may further comprise ridges located on a second, opposite side of the membrane and extending perpendicularly to the first beam.

Further to the characteristics just discussed in the preceding paragraphs, the electromechanical system according to the present invention may have one or several complementary characteristics from among the following, considered individually or according to any technically possible combination:
the movable element is in translation relative to the frame;
the movable element is in rotation relative to the frame;
the frame comprises a cap provided with an opening to provide access to the movable element and the cap comprises a first arm extending through the opening to the first island;
a plurality of first openings are arranged in the movable element, the frame comprises a plurality of first islands, each first island extending into one of the first openings, and the first transmission device is connected to at least part of the first islands via part of the first pivot hinges;
the capacitive measurement or actuation device comprises:
   a first electrode movable relative to the frame; and
   at least one electrode fixed relative to the frame and separated from the first movable electrode by a first dielectric medium;
the first movable electrode is connected to the first transmission shaft;
the first movable electrode is integral with the first transmission shaft, and as a result, the first movable electrode is rotatably movably mounted about the first longitudinal axis of rotation;
the movable element is in contact with a first zone, and the first movable electrode is located in a second zone sealingly isolated from the first zone;
at least one of the first pivot hinges is located at the first movable electrode;
another of the first pivot hinges is located at one end of the first transmission device and connects the first transmission device to the first island;
the system also comprises a second movement transmission device for a movement between the movable element and the capacitive measurement or actuation device, the second transmission device being rotatably movable relative to the frame by a plurality of second pivot hinges;
a second opening is arranged in the movable element, the frame comprises a second island extending into the second opening and the second movement transmission device is connected to the second island via one of the second pivot hinges;
a portion of the second island forms a stop for limiting displacement of the movable element;
the cap comprises a second arm extending through the opening to the second island;
several second openings are arranged in the movable element, the frame comprises a plurality of second islands, each second island extending into one of the second openings, and the second transmission device is connected to at least part of the second islands via part of the second pivot hinges;
the second transmission device comprises:
   a second transmission shaft having a second longitudinal axis of rotation;
   at least one second transmission arm comprising a first end coupled to the movable element and a second end integral with the second transmission shaft;
the capacitive measurement or actuation device further comprises:
   a second electrode movable relative to the frame; and
   at least one additional electrode fixed relative to the frame and separated from the second movable electrode by a second dielectric medium;
the second movable electrode is connected to the second transmission shaft;
the second movable electrode is integral with the second transmission shaft, and as a result, the second movable electrode is rotatably movably mounted about the second longitudinal axis of rotation;
the second movable electrode is located in the second zone;
at least one of the second pivot hinges is located at the first movable electrode; and
another of the first pivot hinges is located at one end of the first transmission device and connects the first transmission device to the first island.

### BRIEF DESCRIPTION OF THE FIGURES

Further characteristics and advantages of the invention will be become apparent from the description thereof given below, by way of indicating and in no way limiting purposes, with reference to the appended figures, wherein:

FIG. 1 is a partial perspective view of a capacitive detection microphone according to prior art;

FIG. 2 is a partial bottom view of an electromechanical system according to a first embodiment, this electromechanical system comprising capacitive detection or actuation device;

FIG. 3 is a partial top view of the capacitive detection or actuation device of the electromechanical system of FIG. 2;

FIG. 4A is a cross-section view of the electromechanical system along the sectional plane A-A of FIG. 3;

FIG. 4B is a cross-section view of the electromechanical system along the sectional plane C-C of FIG. 3;

FIG. 5 is a partial bottom view of an electromechanical system according to a second embodiment;

FIG. 6 is a partial top view of the electromechanical system of FIG. 5;

FIGS. 7A and 7B represent part of an island extending through the movable element of the electromechanical system of FIGS. 5 and 6;

FIG. 8 represents a first example of a cap to which the island of FIGS. 7A-7B is attached;

FIG. 9 represents a second example of a cap to which the island of FIGS. 7A-7B is attached; and

FIG. 10 is a partial bottom view of an electromechanical system according to a third embodiment.

For greater clarity, identical or similar elements are identified by identical reference signs throughout the figures.

### DETAILED DESCRIPTION

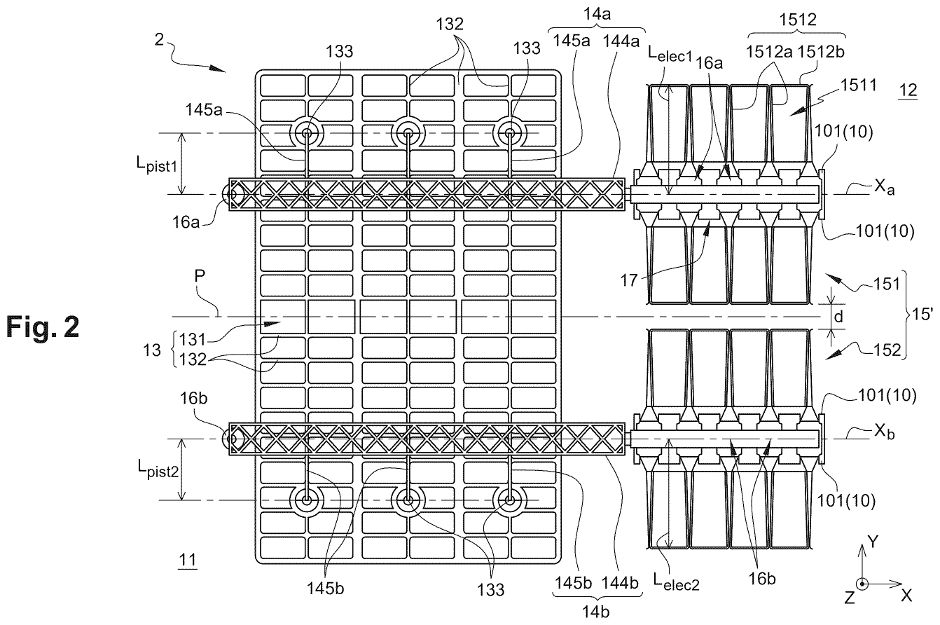

FIGS. 2, 3 and 4A to 4B represent part of an electromechanical system 2 with capacitive detection or capacitive actuation according to a first embodiment. This electromechanical system 2 may form an electroacoustic transducer, for example of a microphone or a loudspeaker, or a differential pressure sensor. In the following description, the example of a capacitive detection microphone will be used.

The electromechanical system 2 comprises:
a frame 10;
a movable element 13 in contact with a first zone 11;
capacitive detection (or measurement) device or capacitive detector 15′ comprising a first electrode 151 movable relative to the frame 10, a second electrode 152 movable relative to the frame 10, the first and second movable electrodes 151-152 being located in a second zone 12 sealingly isolated from the first zone 11; and
a first movement transmission device 14a for a movement between the movable element 13 and the first movable electrode 151 (in other words between the first zone 11 and the second zone 12); and
a second movement transmission device 14b for a movement between the movable element 13 and the second movable electrode 152.

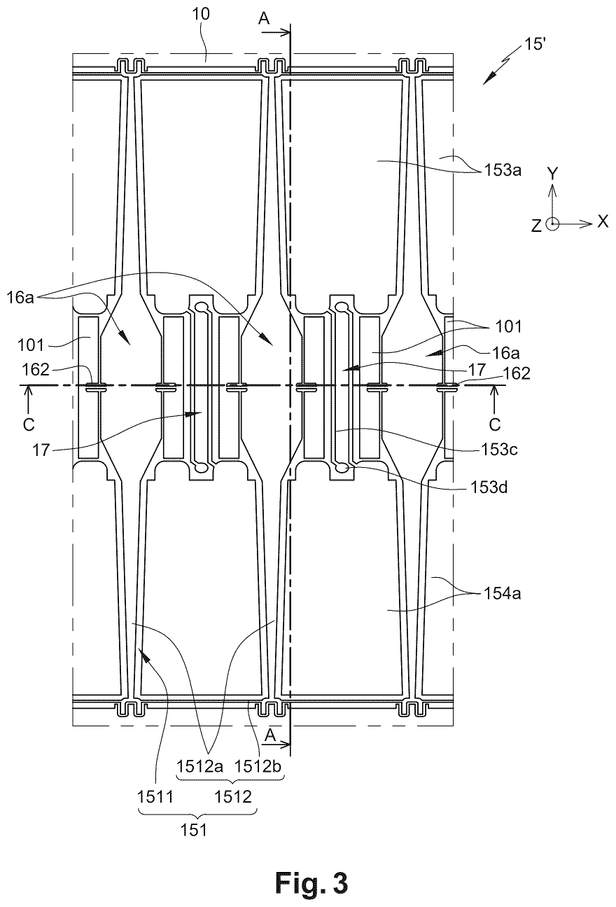

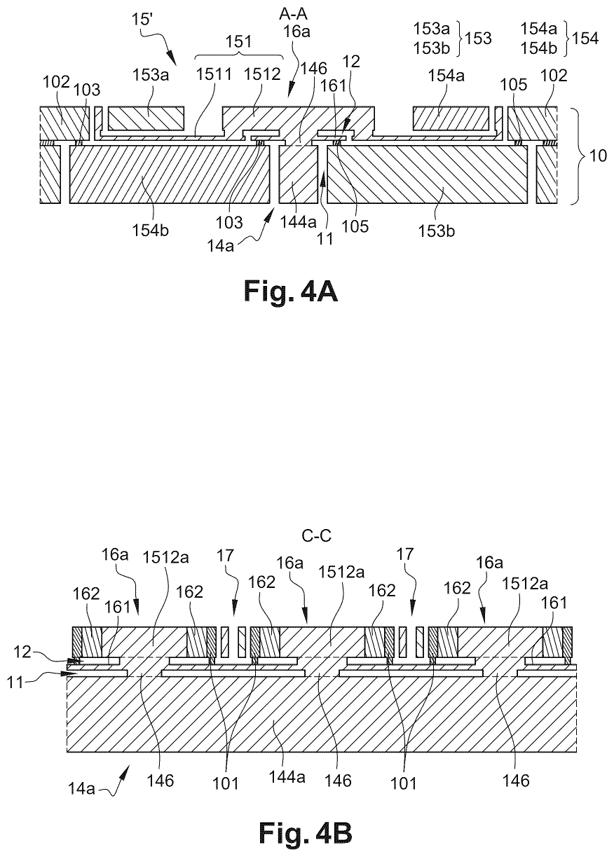

FIG. 2 is a bottom view of the electromechanical system 2 showing first portions 101 of the frame 10, the movable element 13, the transmission devices 14a-14b and the movable electrodes 151-152 of the capacitive detector 15′. FIG. 3 is a top view showing only part of the capacitive detector 15′ (including the first movable electrode 151). FIGS. 4A to 4B are different cross-section views of the electromechanical system 2, respectively in the cross-sectional planes A-A and C-C represented in FIG. 3. They partly represent the frame 10, the first transmission device 14a and the capacitive detector 15′.

The frame 10 is comprised of fixed parts of the electromechanical system 2.

The movable element 13, hereinafter referred to as the piston, is herein translationally movable relative to the frame 10, in a direction (Z) perpendicular to the plane (XY) of FIG. 2. In an embodiment, it comprises a membrane 131 and a rigidifying structure 132 for the membrane 131, also referred to as a backbone or armature. The role of the membrane 131 of the piston 13 is to collect, over its entire surface, a pressure difference between its two faces, in order to deduce a variation in atmospheric pressure.

The membrane 131 of the piston 13 can partly delimit a so-called closed reference volume, where a reference pressure prevails. It separates this reference volume from a cavity open to the external environment. One face of the membrane 131 is therefore subjected to the reference pressure and an opposite face of the membrane 131 is subjected to atmospheric pressure (the variation of which is desired to be detected in the case of a microphone). Alternatively, the reference volume can be nearly closed, in the sense that there is a trench around the piston (which is cut away). This trench allows the piston to move and allows air to leak between the reference volume and the external environment. This leakage is small enough to allow pressures to equalise slowly, so that only low-frequency pressure variations are filtered out.

The first zone 11 encompasses the cavity open to the external environment, subject to atmospheric pressure, and the reference volume subject to reference pressure.

The capacitive detector 15′ make it possible to measure displacement of the piston 13, and therefore the pressure difference between its two faces. Further to the first and second movable electrodes 151-152, they comprise at least one fixed electrode (relative to the frame 10), separated from the first movable electrode 151 by a first dielectric medium, and at least one additional fixed electrode, separated from the second movable electrode 152 by a second dielectric medium.

Each movable electrode and associated fixed electrode(s) form the plates of one or several capacitors whose capacitance varies as a function of the displacement of the piston 13. The fixed electrodes may also be called “counter-electrodes”.

The first dielectric medium and the second dielectric medium are not solid (but are desirably constituted by a gas or a mixture of gases), so as not to impede movement of the movable electrodes 151-152. The second dielectric medium is herein identical to the first dielectric medium, as the movable electrodes 151-152 are both located in the second zone 12.

The second zone 12 is advantageously a controlled atmosphere chamber to reduce viscous friction phenomena and associated acoustic noise. By “controlled atmosphere chamber”, it is meant a chamber under reduced pressure, typically less than 1000 mbar, and in an embodiment less than 1 mbar. Thus, the second zone 12 is here subjected to a pressure well below atmospheric pressure or the reference pressure.

The first transmission device 14a is rotatably movably mounted relative to the frame 10, by several first pivot hinges 16a. In an embodiment, it comprises a first transmission shaft 144a and one or several first transmission arms 145a, also known as lever arms.

The first transmission shaft 144a has a first longitudinal axis of rotation Xa (hereinafter referred to as the first axis Xa), which extends in a first direction X. In other words, the first transmission shaft 144a can pivot on itself, about the first axis Xa. It extends facing the piston 13, facing a zone located between the piston 13 and the first movable electrode 151 and facing the first movable electrode 151.

Advantageously, the first movable electrode 151 is integral with the first transmission shaft 144a, which means that there is no relative movement between the first movable electrode 151 and the first transmission shaft 144a. The first movable electrode 151 is therefore also rotatably movably mounted about the first axis Xa.

The electromechanical system 2 is thus devoid of movement transformation members for the movement between the first transmission device 14a and the first movable electrode 151, such as torsion blades for switching from rotation to translation. As a result, no energy is lost in these transformation members (for example by deformation of the torsion blades).

The first transmission arms 145a, for example three in number in FIG. 2, can extend perpendicularly to the first axis Xa, in other words in a second direction Y perpendicular to the first direction X. The first and second directions X-Y together with a third perpendicular direction Z constitute an orthogonal reference frame.

Each first transmission arm 145a comprises a first end coupled to the piston 13 and a second end integral with the first transmission shaft 144a. One or several coupling elements 133 connect the rigidifying structure 132 for the piston 13 to the first end of each first transmission arm 145a. At least part of the coupling elements 133 (for example torsion blades) allow the transition from a translational movement (piston 13) to a rotational movement (first transmission shaft 144a and first movable electrode 151) while strongly coupling their displacement along the third direction Z. These coupling elements 133 are capable of elastic deformation.

The translational movement of the piston 13 causes the first transmission arms 145a, and therefore the first transmission shaft 144a, to rotate about the first axis Xa. This rotational movement is then transmitted to the first movable electrode 151.

The first pivot hinges 16a, for example six in number, are aligned, here in the first direction X. In an embodiment, one of the first pivot hinges 16a is located at the end of the first transmission shaft 144a, on the piston 13 side (i.e. opposite to the first movable electrode 151), while other first pivot hinges 16a are located on the first movable electrode 151 side. As will be described in detail below, in an embodiment, the first movable electrode 151 is connected to the first transmission shaft 144a at these other first pivot hinges 16a.

The second transmission device 14b is also rotatably movably mounted relative to the frame 10, by second pivot hinges 16b. In an embodiment, it is constructed in the same way as the first transmission device 14a. More particularly, it comprises a second transmission shaft 144b having a second longitudinal axis of rotation Xb (hereinafter referred to as the second axis Xb) and second transmission arms 145b (for example three). Each second transmission arm 145b comprises a first end coupled (via one or several coupling elements 133) to the piston 13 and a second end integral with the second transmission shaft 144b. In an embodiment, the second transmission arms 145b extend perpendicularly to the second axis Xb.

Advantageously, the second movable electrode 152 is integral with the second transmission shaft 144b and therefore rotates about the second axis Xb.

In an embodiment, the second pivot hinges 16b are distributed along the second axis Xb in the same way as the first pivot hinges 16a are distributed along the first axis Xa (one of them is located at the end of the second transmission shaft 144b and others are located at the second movable electrode 152).

The first transmission arms 145a are coupled to a first half of the piston 13 (the upper half in FIG. 2) and the second transmission arms 145b are coupled to a second half of the piston 13 (the lower half in FIG. 2). Thus, the transmission devices 14a-14b support the piston 13 and maintain it in a translational movement. In an embodiment, the piston 13 is held solely by the first and second transmission arms 145a-145b. Thus, a greater proportion of energy collected by the piston 13 is transmitted to the movable electrodes 151-152.

As is illustrated in FIG. 2, the first axis Xa and the second axis Xb are advantageously parallel to each other. This helps to reduce the overall size of the electromechanical system 2 and provides uniform support for the piston.

The first movable electrode 151 and the second movable electrode 152 can be identical and disposed symmetrically with respect to a plane P separating the first and second halves of the piston 13. This symmetry enables an identical reaction to be obtained on the two halves of the piston so that the latter is held securely in translation.

The first transmission device 14a and the second transmission device 14b can also be symmetrical with respect to the plane P. The first transmission shaft 144a and the first movable electrode 151 then pivot in one sense (about the first axis Xa), while the second transmission shaft 144b and the second movable electrode 152 pivot in the opposite sense (about the second axis Xb).

The piston 13 can also be symmetrical about the plane P.

The symmetries of the piston 13 and the transmission devices 14a-14b enable energy collected by the piston 13 to be equally distributed between the first movable electrode 151 and the second movable electrode 152. Indeed, the force exerted by the piston 13 is equally distributed between the first and second halves, and therefore between the first and second transmission devices 14a-14b.

Rotatably mounting the first movable electrode 151 and the second movable electrode 152 along the same axis of rotation as the first transmission device 14a and the second transmission device 14b respectively, makes it possible to obtain a greater displacement of the movable electrodes 151-152 for a given displacement of the piston 13, without however increasing the overall size of the electromechanical system 2. The movable electrodes 151-152 can therefore be moved as close as possible to the piston 13.

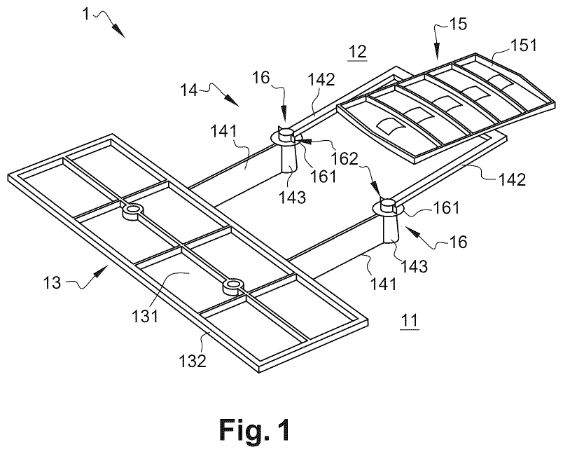

The change from one movable electrode (FIG. 1) to two movable electrodes (FIG. 2) also does not significantly increase the overall size of the electromechanical system 2, as the two movable electrodes 151-152 can be arranged opposite each other as an extension of the piston 13.

The displacement of each movable electrode 151, 152 relative to that of the piston 13 is a function of the distance Lₚᵢₛₜ₁, Lₚᵢₛₜ₂ between the first end of the transmission shafts 145a, 145b and the corresponding axis of rotation Xa, Xb. This distance may be of the same order of magnitude as the distance L_{elec1}, L_{elec2} between a longitudinal edge (i.e. along X) of the movable electrode 151, 152 and the axis of rotation Xa, Xb.

More precisely, the Z displacement of the longitudinal edge of the first movable electrode 151 is given by the following relationship:

$${d}_{Zelec 1} = \frac{{L}_{elec 1}}{{L}_{pist 1}} \times {d}_{Zpist} \qquad [ Math . 1 ]$$

where d_{Zpist} is the Z displacement of the piston 13 (and therefore of all the first ends of the first and second transmission arms 145a-145b), L_{elec1} is the distance between the longitudinal edge of the first movable electrode 151 and the first axis Xa and Lₚᵢₛₜ₁ is the distance between the first end of each first transmission arm 145a and the first axis Xa.

The Z displacement of the longitudinal edge of the second movable electrode 152 is given by the following relationship:

$${d}_{Zelec 2} = \frac{{L}_{elec 2}}{{L}_{pist 2}} \times {d}_{Zpist} \qquad [ Math . 2 ]$$

where L_{elec2} is the distance between the longitudinal edge of the second movable electrode 152 and the second axis Xb and Lₚᵢₛₜ₂ is the distance between the first end of each second transmission arm 14b and the second axis Xb.

The transmission shafts 144a-144b and the transmission arms 145a-145b can be particularly rigid, and therefore not very sensitive to deformations which are equivalent to energy losses. This rigidity of the transmission shafts 144a-144b and the transmission arms 145a-145b can especially be conferred by a substantial thickness (measured in the third direction Z), such as between 5 μm and 800 μm, and for example between 50 μm and 200 μm. The transmission shafts 144a-144b and the transmission arms 145a-145b are advantageously formed by etching a substrate. This substrate can be thinned to a thickness of less than 200 μm.

As the transmission shafts 144a-144b rotate about themselves, their inertia remains low and does not have a negative impact on the resonant frequency of the electromechanical system 2. However, they can be perforated, as is illustrated in FIG. 2, in order to optimise their rigidity to inertia ratio. The transmission shafts 144a-144b are in an embodiment perforated at least in the portion facing the piston 13. This also makes it possible to limit damping with the piston 13 (a phenomenon referred to as “squeeze film damping”), which is a source of noise.

The width of the transmission shafts 144a-144b (measured in the first direction Y) is of the same order of magnitude as their thickness, in order to minimise their inertia. Advantageously, it is between 5 μm and 800 μm.

The capacitive detector 15′ will now be described in more detail, referring only to the first movable electrode 151 (connected to the first transmission device 14a). However, this description applies mutatis mutandis to the second movable electrode 152 (connected to the second transmission device 14b), since it may be identical to the first electrode 151. Similarly, the description that will be made about the first pivot hinges 16a applies to the second pivot hinges 16b.

With reference to FIGS. 2 and 3, the first electrode 151 may comprise a membrane 1511 and a rigidifying structure 1512 for the membrane 1511. The rigidifying structure 1512 in an embodiment comprises a plurality of first beams 1512a extending in parallel to one another. It may further comprise second beams 1512b connecting the first beams 1512a at their ends.

The first beams 1512a in an embodiment extend in the second direction Y, advantageously from a first edge to an opposite second edge of the first movable electrode 151. They are advantageously evenly spaced from one another, to rigidify the membrane 1511 uniformly. The second beams 1512b in an embodiment extend in the first direction X (thus perpendicularly to the first beams 1512a).

The first movable electrode 151 advantageously has one or several planes of symmetry, for example a plane parallel to the plane XZ (therefore perpendicular to the first beams 1512a) and another plane parallel to the plane YZ.

The rigidifying structure 1512 of the first movable electrode 151 is advantageously anchored, or merged, to the first transmission device 14a at part of the first pivot hinges 16a. Compared with the microphone 1 of FIG. 1, the electrostatic system 2 is therefore devoid of the second transmission arms 142 extending through the second zone 12.

More particularly, the rigidifying structure 1512 for the first movable electrode 151 is connected to the first transmission device 14a, and more particularly to the first transmission shaft 144a, by pillars 146 visible in FIGS. 4A and 4B. The pillars 146 of the first transmission device 14a are similar to the transmission shafts 143 of FIG. 1, in that they extend partly into the first zone 11 and partly into the second zone 12. Indeed, sealing between the first zone 11 and the second zone 12 is also ensured at the first pivot hinges 16a associated with the first movable electrode 151.

The first transmission device 14a is thus reduced to first elements exclusively extending through the first zone 11 (the first transmission shaft 144a and the first transmission arms 145a) and to second elements (the pillars 146) which extend partly through the first zone 11 and partly through the second zone 12. This reduction of the first transmission device 14a makes it possible to limit energy losses. There are especially no more losses due to deformation of the second transmission arms 142.

The electromechanical system 2 is particularly compact, as several functions, namely rotating the first transmission device 14a, sealing between the two zones 11-12 and connecting to the first movable electrode 151, are carried out in the same place.

Anchoring between the rigidifying structure 1512 and the first transmission device 14a is in an embodiment achieved by first beams 1512a. At least part of these are merged to the first transmission device 14a, each at a corresponding first pivot hinge 16a. The anchoring point of each first beam 1512a is advantageously located halfway along its length. Thus, the axis of rotation of the first movable electrode 151 lies in one of the planes of symmetry of the first movable electrode 151 (that perpendicular to the first beams 1512a). The length of the first beams 1512a is measured in the second direction Y, while their width is measured in the first direction X.

Each first beam 1512a merged with the first transmission device 14a advantageously has a width which decreases with distance from the corresponding first pivot hinge 16a.

In this first embodiment of the electromechanical system 2, each of the first beams 1512a of the rigidifying structure 1512 is merged to the first transmission device 14a. In other words, each first beam 1512a is associated with a first pivot hinge 16a. The number of first pivot hinges 16a on the side of the first movable electrode 151 is therefore equal to the number of first beams 1512a. This arrangement makes it possible to arrange a space 17 between two successive first pivot hinges 16a.

The frame 10 may comprise, for each first pivot hinge 16a, two distinct first portions 101 arranged on either side of the first beam 1512a associated with the first pivot hinge. The first beam 1512a is in an embodiment connected to each of the first portions 101 of the frame 10 by a torsion blade 162 (see FIG. 3).

As is represented by FIGS. 3, 4A to 4B, the capacitive detector 15′ in an embodiment comprise two counter-electrodes 153-154 associated with the first movable electrode 151: a first, so-called positive, counter-electrode 153 and a second, so-called, counter-electrode 154. In an embodiment, at least part of the membrane 1511 of the first movable electrode 151 is located between the two counter-electrodes 153-154 (see FIGS. 4A-4B). The first movable electrode 151 and the counter-electrodes 153-154 thus form the plates of two capacitors whose capacitances vary in opposite senses. A differential measurement of the displacement of the piston 13 can thus be obtained. The surface areas of the counter-electrodes 153-154 facing the first movable electrode 151 are advantageously identical, thanks to the symmetry of the first movable electrode 151 and the counter-electrodes 153-154 with respect to the first pivot hinges 16a (the plane of symmetry coincides with the sectional plane C-C).

Advantageously, each of the counter-electrodes 153, 154 comprises a first portion 153a, 154a and a second portion 153b, 154b that are located on either side of the membrane 1511 and on either side of the first pivot hinges 16a. The first portion 153a, 154a, referred to as the upper portion, and the second portion 153b, 154b, referred to as the lower portion, of a same counter-electrode are electrically connected. This arrangement makes it possible to obtain a fully differential measurement, even if the distance between the membrane 1511 and the upper portions 153a-154a of the counter-electrodes (referred to as an upper air gap) is different from the distance between the membrane 1511 and the lower portions 153a-154a of the counter-electrodes (lower air gap).

The lower portions 153b-154b of the counter-electrodes 153-154 extend under the first beams 1512a of the rigidifying structure 1512, on either side of the first pivot hinges 16a. In contrast, the upper portions 153a-154a of the counter-electrodes 153-154 are in an embodiment each divided into several blocks (or sub-portions) separated by the first beams 1512a, as illustrated in FIG. 3. As the upper portions 153a-154a of the counter-electrodes 153-154 are inscribed in the rigidifying structure 1512, their surface area facing the membrane 1511 is smaller than that of the lower portions 153b-154b.

With reference to FIG. 4A, the lower portions 153b-154b of the counter-electrodes 153-154 are in an embodiment secured to an annular portion 102 of the frame 10, located at the periphery of the first movable electrode 151, by annular seals 103, 105 of an electrically insulating material (one annular seal per lower portion 153b, 154b). These annular seals 103, 105, for example of silicon oxide, also provide sealing between the first zone 11 and the second zone 12.

Alternatively, the capacitive detector 15′ may comprise (for each movable electrode) a single (top or bottom) counter-electrode, two, top and bottom, counter-electrodes but located on one side of the pivot hinges 16 (pseudo-differential detection) or even two, top or bottom, counter-electrodes located on either side of the pivot hinges 16 (differential detection).

As previously indicated, sealing between the first and second zones 11-12 of the electromechanical system 2 can be achieved at the first pivot hinges 16a located on the side of the first movable electrode 151. As illustrated in FIGS. 4A and 4B, each first pivot hinge 16a associated with the first movable electrode 151 comprises a sealed isolation element 161, capable of elastically deforming under the effect of the rotational displacement of the first transmission device 14a. The sealed isolation element 161 is in an embodiment in the form of a sealing membrane.

Each sealed isolation element 161 has in an embodiment an associated pillar 146 of the first transmission device 14a passing therethrough. The sealed isolation element 161 extends, for example, from the associated pillar 146 to the lower portions 153b-154b of the counter-electrodes 153-154 (see FIG. 4A) and to the first portions 101 of the frame 10 (see FIG. 4B), to which it is anchored by the annular seals 103, 105 of electrically insulating material.

In addition, each first pivot hinge 16a (associated with the first movable electrode 151) advantageously comprises two torsion blades 162 (one per first portion 101 of the frame 10). The torsion blades 162 are dimensioned so as to be able to deform (elastically) in torsion and allow rotation of the first transmission device 14a and of the first movable electrode 151, while limiting their translational movements, especially along the third direction Z (so-called “out-of-plane” translation). The two torsion blades 162 connect the rigidifying structure 1512 for the first movable electrode 151 (merged to the pillar 146 of the first transmission device 14a) to the first portions 101 of the frame 10 (see also FIG. 4B). They are in an embodiment aligned and arranged diametrically opposite to the first beam 1512a associated with the first pivot hinge 16a.

The first pivot hinge 16a located at the end of the first transmission shaft 144a advantageously comprises a sealed isolation element 161 (in an embodiment in the form of a membrane) and two torsion blades 162, but does not participate in the sealing between the first and second zones 11-12 (being located only in the first zone 11).

The electromechanical system 2 comprises elastic device connected to the first movable electrode 151 and configured to generate an elastic force which opposes to the movement of the first movable electrode 151. The role of these elastic device is to combat the pull-in phenomenon of the first movable electrode 151. Their stiffness (spring constant) influences the “pull-in voltage” of the system, and therefore the ability to bias the first movable electrode 151.

The “anti-pull-in” elastic device connects (mechanically) the rigidifying structure 1512 for the first movable electrode 151 to the frame 10 and/or to elements integral with the frame, such as the counter-electrodes 153-154, possibly via the pillars 146 of the first transmission device 14a. Thus, the stiffness (spring constant) of the first transmission device 14a or the stiffness (spring constant) of the rigidifying structure 1512 itself are not considered to be “anti-pull-in” elastic device.

The “anti-pull-in” elastic device here comprises the sealed isolation elements 161 and, where appropriate, the torsion blades 162. The sealed isolation elements 161 and the torsion blades 162 thus fulfil several functions simultaneously.

The anti-pull-in elastic device is connected to the rigidifying structure 1512 where it is most rigid, i.e. at the first pivot hinges 16a. Thus, the stiffness (spring constant) of the anti-pull-in elastic device is not degraded by series elements of too low stiffness (spring constant). This stiffness (spring constant) can also be easily controlled by adjusting the dimensions of the sealed isolation elements 161 and of the torsion blades 162. The sealed isolation elements 161 can be defined by anisotropically etching a sacrificial layer (for example of SiO₂) and are made in a structural layer of controlled thickness. This type of etching gives good control over the dimensions of the insulating elements 161. As a result, the stiffness (spring constant) of the sealed isolation elements 161 shows little dispersion (mainly between the different electromechanical systems manufactured on a same wafer or on different wafers).

The second movable electrode 152 is advantageously connected to the second transmission device 14b in the same way as the first movable electrode 151 is connected to the first transmission device 14a. Thus, the electromechanical system 2 also comprises “anti-pull-in” elastic device connected to the second movable electrode 152, the elastic device in an embodiment comprising the sealed isolation elements 161 and, where appropriate, the torsion blades 162 of the second pivot hinges 16b.

The sealed isolation elements 161 and, where appropriate, the torsion blades 162, advantageously constitute the only “anti-pull-in” device of the electromechanical system 2. Thus, the electromechanical system 2 is particularly compact.

The electromechanical system 2 described above can be manufactured using the methods described in patents FR3059659B1 and FR3114584B1, especially starting from a stack of layers comprising successively a substrate, a first sacrificial layer and a first structural layer. The stack can especially be a multilayer structure of the Silicon-On-Insulator (SOI) type, commonly known as an SOI substrate.

The substrate is especially used to produce, by etching, the first elements of the transmission devices 14a-14b (transmission shafts 144a-144b and transmission arms 145a-145b), the lower portions 153b-154b of the counter-electrodes 153-154 and part of the frame 10. The substrate may be of a semiconductor material, for example of silicon.

The first structural layer is used especially to make the membrane 131 of the piston 13, the membrane 1511 of the movable electrodes 151-152 and the sealed isolation elements 161 (sealing membranes). Its thickness is less than that of the substrate, such as between 100 nm and 10 μm. It may consist of the same material as the substrate, for example silicon.

The first sacrificial layer is intended to partly disappear during manufacture of the electromechanical system 2 to release the membrane 131 of the piston 13, the membrane 1511 of the movable electrodes 151-152 and the sealed isolation elements 161. Its thickness especially defines the distance between the membrane 1511 and the lower portions 153b-154b of the counter-electrodes 153-154 (lower air gap). This layer also acts as a stop layer during etching of the substrate, the membrane 152a and the second structural layer (so-called “MEMS” layer described later). The remaining parts of the first sacrificial layer form the annular seals 103, 105 and the lower pillars 104. The first sacrificial layer can consist of a dielectric material, such as a silicon nitride or a silicon oxide, for example silicon dioxide (SiO₂). Its thickness is, for example, between 100 nm and 10 μm.

As described in the aforementioned patents, a second sacrificial layer is deposited onto the first structural layer and a second structural layer is formed on the second sacrificial layer, such as by epitaxy.

The second structural layer is etched to define at least part of the rigidifying structure 132 for the piston 13, the rigidifying structure 1512 for the movable electrodes 151-152, the torsion blades 162, the upper portions 153a-154a of the counter-electrodes 153-154, the first portions 101 and the second annular portion 102 of the frame 10. It is advantageously formed of the same material as the first structural layer, for example silicon. The thickness of the second structural layer is in an embodiment between 5 μm and 50 μm.

The rigidifying structure 1512 for each movable electrode 151, 152 is merged to the corresponding transmission device 14a, 14b, by growing the second structural layer directly from the substrate, at the location of the pivot hinges 16a, 16b (the first and second sacrificial layers having been opened beforehand). The pillars 146 of the transmission devices 14a, 14b are formed during this epitaxial growth.

The second sacrificial layer serves especially as a stop layer during etching of the second structural layer. It is partly removed to release the membrane 131 of the piston 13, the membrane 1511 of the movable electrodes 151-152 and the sealed isolation elements 161. Its thickness defines the distance between the membrane 1511 and the upper portions 153a-154a of the counter-electrodes 153-154 (upper air gap). The second sacrificial layer is advantageously formed of the same dielectric material as the first sacrificial layer, for example silicon oxide. Its thickness can be between 100 nm and 10 μm.

Thus, the frame 10 comprises a part formed by the substrate (in which the transmission devices 14a-14b are also etched) and a part formed by the second structural layer. It also comprises a cap mounted on the second structural layer. This cap is open to the external environment to give access to the piston 13. Additionally, it closes the second zone 12 (the controlled atmosphere chamber) in which the movable electrodes 151-152 of the capacitive detector 15′ is located.

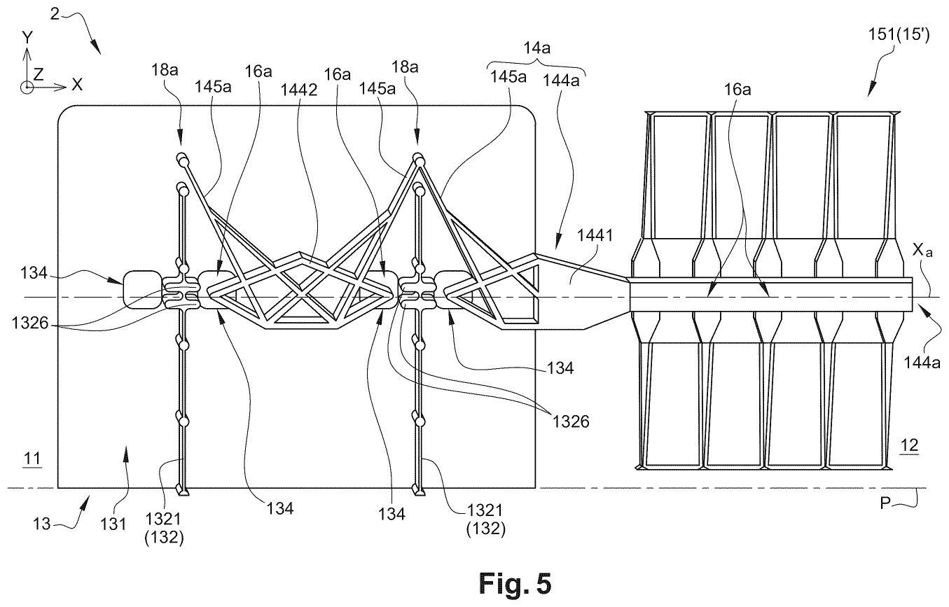

FIGS. 5, 6, 7A and 7B schematically represent a second embodiment of the electromechanical system 2. In this second embodiment, the frame 10 and piston 13 assume a particular configuration enabling the first and second transmission devices 14a-14b to be more rigid and lighter, thus improving performance of the electromechanical system 2 in terms of sensitivity and resonant frequency.

In addition to the frame 10, the piston 13 and the transmission devices 14a-14b, the electromechanical system 2 according to the second embodiment comprises capacitive detector 15′. These capacitive detector 15′ are in an embodiment identical to those of the first embodiment. In particular, they comprise the movable electrodes 151-152 which are constructed and connected to the transmission devices 14a-14b in the manner previously described in connection with FIGS. 2, 3 and 4A-4B.

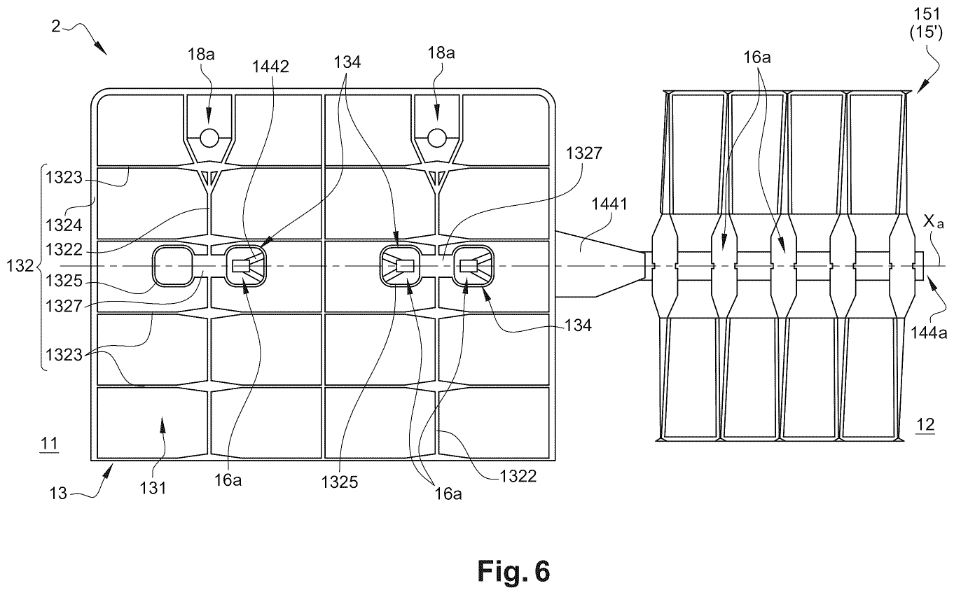

FIG. 5 is a bottom view, similar to FIG. 2, but showing only part of the electromechanical system 2. FIG. 6 is a top view of the same part of the electromechanical system 2. More precisely, only one half of the piston 13, the first movable electrode 151 and the first transmission device 14a are represented in FIGS. 5 and 6. As previously, the piston 13 is advantageously symmetrical with respect to the plane P, as are the transmission devices 14a-14b and the movable electrodes 151-152

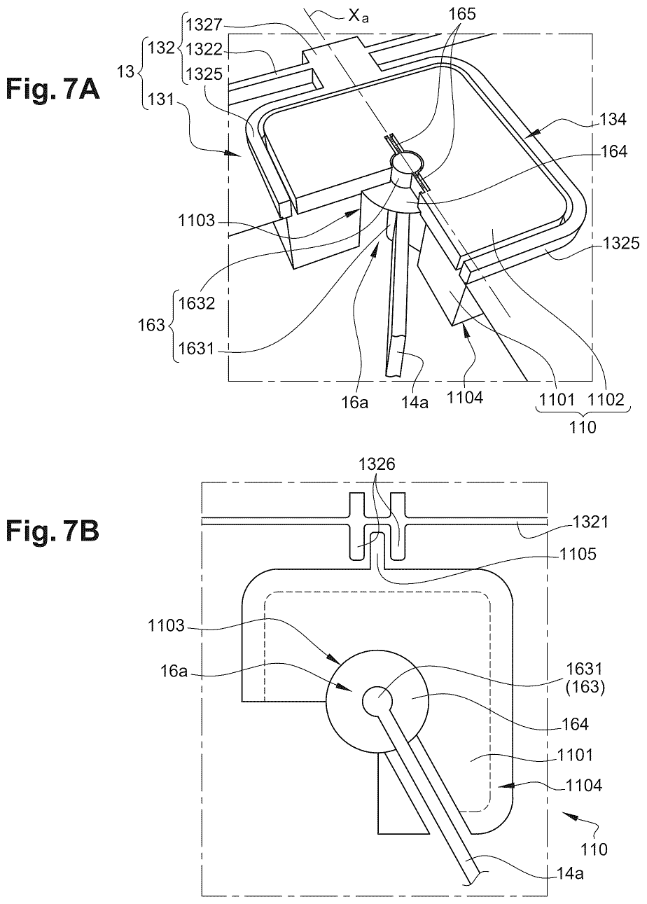

The electromechanical system 2 of FIGS. 5-6, 7A-7B differs from that of FIG. 2 especially in that a first opening 134 is arranged in the piston 13 (cf. FIGS. 5-6) and in that the frame 10 comprises a first island 110 (visible only in FIGS. 7A-7B) which extends into the first opening 134. The first transmission device 14a is connected to the first island 110 via one of the first pivot hinges 16a.

As the first island 110 belongs to the frame 10, it constitutes a fixed point in the zone of the piston 13, to which the first transmission device 14a is connected.

Such an anchoring point located within the perimeter of the piston 13 allows the first transmission device 14a to be shorter (compared to that of FIG. 2), and therefore more rigid and lighter. Indeed, the first transmission device 14a no longer needs to extend to the zone peripheral to the piston 13, opposite to the first movable electrode 151.

The first island 110 therefore improves performance of the electromechanical system 2 by limiting energy losses through deformation of the first transmission device 14a and reducing its mass, even though the useful surface area of the piston 13 is reduced because of the first opening 134.

One of the first pivot hinges 16a is thus located at the first opening 134, inside the perimeter of the piston 13. The other first pivot hinge(s) 16a may be located at the first movable electrode 151, as described previously in connection with FIG. 2.

As is represented in FIGS. 5 and 6, several first openings 134 may be arranged in the piston 13. The frame 10 then advantageously comprises several first islands 110, each first island 110 extending into a first opening 134, so as to form several fixed points to which the first transmission device 14a is connected. The first transmission device 14a is connected to at least part of the first islands 110 via part of the first pivot hinges 16a, at the rate of one first pivot hinge 16a per first island 110.

The number of first openings 134 in the piston 13 may be greater than or equal to the number of first islands 110. However, it is in an embodiment equal to the number of first islands 110 in order to maximise the useful surface area of the piston 13.

A first island 110 connected to the first transmission device 14a by a first pivot hinge 16a is hereinafter referred to as the “first hinged island”.

By increasing the number of first hinged islands, the first transmission device 14a is better supported and even less likely to deform. Energy losses through deformation of the first transmission device 14a are therefore even more limited.

As in the first embodiment, the first transmission device 14a in an embodiment comprises:
a first transmission shaft 144a, rotating about its longitudinal axis Xa;
one or several first transmission arms (or lever arms) 145a each having a first end integral with the first transmission shaft 144a and a second end coupled to the piston 13.

Providing at least one fixed point inside the perimeter of the piston 13 also makes it possible to “split” the first transmission shaft 144a into several distinct portions, which makes it possible to further rigidify the piston 13 by disposing part of the rigidifying structure 132 between these portions. Indeed, in the embodiment of FIG. 2, the first transmission shaft 144a continuously extends in the first direction X between the first movable electrode 151 and the first pivot hinge 16a located opposite to and beyond the piston 13. The rigidifying structure 132 cannot therefore extend continuously in the second direction Y, on the side of the piston 131 where the first transmission shaft 144a is located.

Here, the first transmission shaft 144a advantageously comprises two distinct portions: a first portion 1441 which extends to the capacitive detector 15′ and a second portion 1442 connected to one or several first islands 110.

The rigidifying structure 132 for the piston 13 advantageously comprises, on the side of the membrane 131 where the first transmission shaft 144a is located, two first beams 1321, one of which is disposed between the first and second portions 1441-1442 of the first transmission shaft 144a. The first two beams 1321 are in an embodiment parallel to each other. They extend here in a direction perpendicular to the first axis Xa, in other words in the second direction Y.

The direction of the first beams 1321 corresponds here to the direction in which the length of the piston is measured, i.e. its largest dimension.

The first beams 1321 advantageously have the same thickness as the first transmission shaft 144a and the first transmission arms 145a, i.e. a thickness of between 5 μm and 800 μm, such as between 50 μm and 200 μm. It is formed at the same time as the first transmission shaft 144a and the first transmission arms 145a, by etching the substrate.

Thanks to their significant thickness, the first beams 1321 make a major contribution to rigidifying the piston 13 (here in its length direction) and therefore to reducing deformation of the piston 13. They therefore provide a significant performance gain divided up between sensitivity and/or resonant frequency.

Each of the first beams 1321 in an embodiment extends over more than 50% of the dimension of the piston 13 measured in the second direction Y.

The fact that the first beams 1321 can pass through the first transmission device 14a considerably increases rigidity of the piston 13 and/or otherwise makes it possible to lighten its rigidifying structure 132. Thus, improved performance is also achieved by optimising the rigidifying structure 132.

In an embodiment, on the side of the membrane 131 where the first transmission shaft 144a is located, the rigidifying structure 132 only comprises the first beams 1321.

On the other side of the membrane 131, represented in FIG. 6, the rigidifying structure 132 for the piston 13 advantageously comprises two second beams 1322 superimposed on the first beams 1321. These second beams 1322 have a thickness strictly less than that of the first beams 1321. They can be formed in the second structural layer described above, the thickness of which is between 5 μm and 50 μm. Each second beam 1322 may have a length equal to that of the first beam 1321 associated therewith (or superimposed thereto).

Each second beam 1322 is thus an at least partial extension of the first beam 1321 associated in the third direction Z to achieve a greater thickness. The second beams 1322 increase the mass of the piston 13 only slightly (to a lesser extent than the first beams 1321, due to its smaller thickness), but considerably increase rigidity of the piston (as this varies as a function of the cubed thickness).

On the same side as the second beams 1322, the rigidifying structure 132 may also comprise ridges 1323 oriented perpendicularly to the first beams 1321 (so in an embodiment in parallel to the first axis Xa). These ridges 1323 rigidify the piston 13 in its dimension along X (here its width). The ridges 1323 do not need to be thick (unlike the first beams 1321), as the connections with the first transmission device 14a (first hinges 18a) also contribute to rigidifying the piston 13 along X. The ridges 1323 in an embodiment have the same thickness as the second beams 1322 (between 5 μm and 50 μm). Thus, they do not significantly increase the mass of the piston 13. They are also formed by etching the second structural layer. They can extend from one edge of the piston 13 to the other.

A part at least of the ridges 1323 may bear against stop elements belonging to the frame of the electromechanical system 2. These stop elements, for example in the form of a beam extending facing the ridges 1323, are designed to prevent destruction of the piston 13 and the movable electrodes 151-152 when the piston 13 is subjected to a very large pressure difference (such as during reliability tests).

The rigidifying structure 132 may also comprise a frame 1324 located at the periphery of the piston 13. This frame 1324 in an embodiment has the same thickness as the second beams 1322. It may also be formed by etching the second structural layer.

Finally, for each first opening 134 in the membrane 131 of the piston 13, the rigidifying structure 132 may comprise a ring 1325 around the first opening 134 and forming a rim. This ring 1325 in an embodiment has the same thickness as the second beams 1322. It can also be formed by etching the second structural layer.

In the example of FIGS. 5 and 6, the second portion 1442 of the first transmission shaft 144a is located between the first two beams 1321. It is held in rotation by two first pivot hinges 16a each connected to a first island 110. The first pivot hinges 16a are in an embodiment located at the ends of the second portion 1442.

The first portion 1441 of the first transmission shaft 144a is held in rotation by several first pivot hinges 16a located at the first movable electrode 151, and advantageously, by a first additional pivot hinge 16a located in the zone of the piston 13 (and therefore connected to a first island 110). This first additional pivot hinge 16a is in an embodiment located at one end of the first portion 1441 (end furthest away from the capacitive detector 15′).

In addition, the piston 13 is connected to the first transmission device 14a by two first hinges 18a. These first hinges 18a are in an embodiment located as an extension of the first beams 1321. The first transmission device 14a thereby comprises several first transmission arms 145a which extend from the first transmission shaft 144a to either of the first hinges 18a. Providing several first transmission arms 145a limits torsion of the first transmission device 14a.

The first transmission device 14a especially comprises two first transmission arms 145a which converge towards a same first hinge 18a. One of these two first transmission arms 145a extends from the first portion 1441 of the first transmission shaft 144a and the other extends from the second portion 1442 of the first transmission shaft 144a.

Providing several first hinges 18a between the piston 13 and the first transmission device 14a (and therefore several first transmission arms 145a) makes it easier to hold the piston 13 in a plane parallel to the plane XY and to distribute forces more evenly, especially in the case of a piston 13 with large dimensions.

As the piston 13 is coupled to the first transmission device 14a at several points (here two), it can be considered that the piston 13 is comprised of several parts (here two) arranged side by side in the first direction X and each reinforced by a first beam 1321. The X rigidity of piston 13 can therefore be assessed on only one part of the piston. Advantageously, the X dimension of each part of the piston is less than the Y dimension of the entire piston. However, the X dimension of the whole piston may be greater than its Y dimension (i.e. X length and Y width).

For a piston with a reduced surface area, the rigidifying structure 132 may comprise only a single first beam 1321 arranged between the two portions of the first transmission shaft 144a. This first beam 1321 has advantageously a single second beam 1322 thereabove. Furthermore, the electromechanical system 2 may comprise only a single first hinge 18a between the piston 13 and the first transmission device 14a, in an embodiment located as an extension of the single first beam 1321.

Conversely, for a piston with a larger surface area, the first transmission shaft 144a may comprise more than two distinct portions. The portions other than that extending to the capacitive detector 15′ are held in rotation by one or several (such as two) first islands 110 each. In addition, the rigidifying structure 132 may comprise more than two first beams 1321 (advantageously disposed in parallel to each other).

FIGS. 7A-7B represent an example embodiment of a first island 110, connected to the first transmission device 14a via a first pivot hinge 16a.

In this example, the first island 110 comprises a first part 1101 formed by etching the substrate and a second part 1102 formed by etching the second structural layer.

A cavity 1103 is arranged inside the first island 110. The first pivot hinge 16a is located in this cavity 1103.

The first pivot hinge 16a associated with the first island 110 in an embodiment comprises a pillar 163, a membrane 164 and torsion blades 165. The pillar 163 is integral with the first transmission device 14a and free to rotatably move about the first axis Xa inside the first island 110. It extends in the third direction Z from one side to the other of the membrane 131 of the piston 13. A first part 1631 of the pillar 163, located on the same side of the membrane as the first transmission device 14a, is obtained by etching the substrate. A second part 1632 of the pillar 163, located on the opposite side of the membrane, is obtained by etching the second structural layer.

The membrane 164 connects the pillar 163 (between its first and second parts) to the first island 110. It is configured to deform elastically under the effect of the rotational displacement of the first transmission device 14a and to oppose to the movements of the first transmission device 14a in a first direction. It is formed in the first structural layer (like the membrane 131 of the piston 13).

The torsion blades 165, for example two in number, also connect the pillar 163 to the first island 110. More specifically, they connect the second part 1632 of the pillar 163 to the second part 1102 of the first island 110. They are formed by etching the second structural layer.

The torsion blades 165 are dimensioned so as to be able to deform (elastically) in torsion and allow the transmission device 14a to rotate, while limiting its translational movements along the third direction Z. They are in an embodiment aligned and disposed on either side of the pillar 163.

Advantageously, a portion 1104 of the first island 110 is configured to form a stop for limiting displacement of the piston. This portion 1104 of the first island 110 faces the piston 13. Thus, the piston 13 can rest on the portion 1104 of the first island 110 when it is subjected to a very large pressure difference (as during reliability tests). The purpose of this stop is to prevent damaging to the piston 13.

In the example embodiment of FIGS. 7A-7B, the stop is formed by a peripheral portion of the first island 110, and more particularly a peripheral portion of the first part 1101. This peripheral portion protrudes from the second part 1102.

In addition, the first island 110 may comprise a finger 1105 configured to act as a bearing point for the piston 13 between two fingers 1326 of the rigidifying structure 132 (see FIG. 5 & FIG. 7B). The finger 1105 in an embodiment extends from the peripheral portion 1104 of the first island 110.

The fingers 1326 of the rigidifying structure 132 in an embodiment extend from a first beam 1321. Thus, the finger 1105 of the first island 110 acts as a stop and relieves the piston at a point where it is most rigid (in the vicinity of a first beam 1321). On the other side of the membrane 131, the rigidifying structure 132 comprises a portion 1327 which extends above the fingers 1326 but also above the space between the fingers 1326 (see FIG. 7A).

A first island 110, a portion of which forms a stop for the piston 13, is hereinafter referred to as the “first island with stop”.

A first island with a stop (with or without a hinge) makes it possible to absorb forces inside the piston area at a distance from the edges and limit mechanical stresses in the electromechanical system 2.

In an embodiment, the frame 10 comprises at least two first islands with a stop. These first islands may be those which hold the second portion 1442 of the first transmission shaft 144a in rotation. In this case, they are first islands with a stop and a hinge.

The first island 110 to which the first portion 1441 of the first transmission shaft 144a is connected is advantageously an island with a stop and hinge. Thus, the frame 10 comprises two first islands with stop and hinge arranged on either side of the first beam 1321 which separates the two portions of the first transmission shaft 144a.

Thus, in the example of FIGS. 5 and 6, the piston 13 comprises three first openings 134 each accommodating a first island with hinge and stop.

A first additional opening 134 accommodating a first island with a stop but without hinges can be arranged in the piston 13.

The first islands with stops (with or without hinges) are in an embodiment arranged in pairs symmetrically with respect to a first beam 1321. Advantageously, they are each equipped with a finger 1105 housed between two fingers 1326 of the rigidifying structure 132.

One solution for bringing the first islands 110 inside the perimeter of the piston 13 is to use the cap that gives access to the piston.

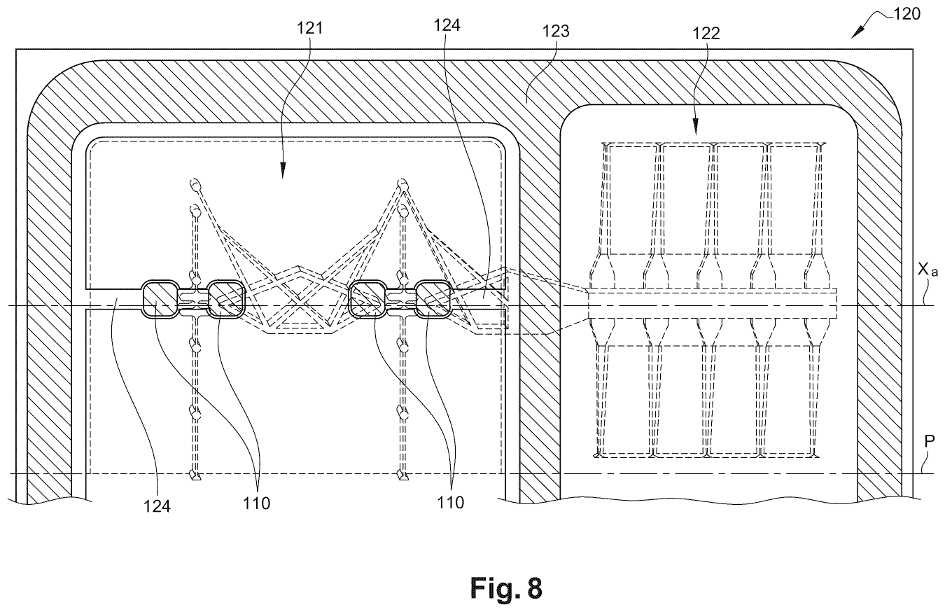

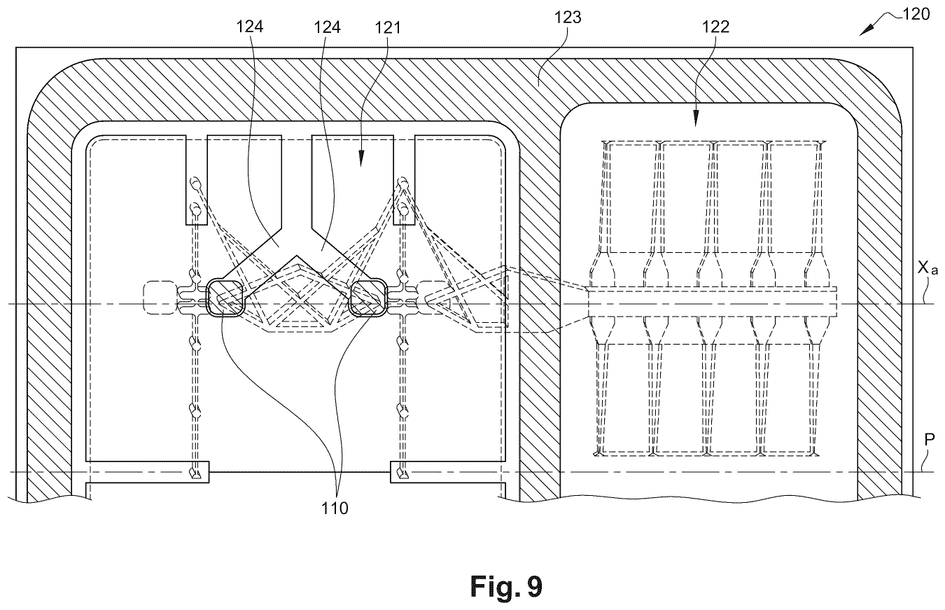

FIGS. 8 and 9 represent two examples of a cap 120. The cap 120 is in an embodiment made by machining or etching a second substrate (for example of silicon).

In common with these two examples, the cap 120 comprises an opening 121 to expose one face of the piston to the external environment. This opening 121 is in an embodiment sized to expose the entire face of the piston. The opening 121 serves as an acoustic port.

In addition, the cap 120 comprises at least one cavity 122, which constitutes part of the second zone (controlled atmosphere chamber) in which the movable electrodes of the capacitive detector is located. The cavity 122 is hollowed out of the second substrate.

The opening 121 and the cavity 122 are surrounded by a sealing zone 123, for attaching the cap 120 to the rest of the frame, and more particularly to the second structural layer. The sealing zone 123 especially ensures sealing of the second zone.

Finally, the cap 120 comprises at least one first arm 124 which extends into the opening 121. One or several first islands 110 are attached to this first arm 124. As is represented in the figures, the cap 120 may comprise several first arms 124, extending from a same edge of the opening 121 or from different edges, in order to attach all the first islands 110.

Each first island 110 is in an embodiment attached to a first arm 124 in the same way as the cap 120 is attached to the rest of the frame 10 in the sealing zone 123, for example by direct bonding (e.g. Si—Si) or eutectic bonding (e.g. Au—Si or Al—Ge).

In the example of FIG. 8, suitable for the configuration of the first islands represented by FIGS. 5 and 6, the cap 120 comprises two arms 124 each for attaching two first islands 110. The arms 124 extend in parallel to the first axis Xa from opposite edges of the opening 121.

In the example of FIG. 9, suitable for a configuration with only two first islands 110 (such as those supporting the second portion 1442 of the first transmission shaft 144a), the cap 120 comprises two arms 124 each for attaching a first island 110. The arms 124 in an embodiment extend from a same edge of the opening 121, in this case the upper edge. The two arms 124 can be adjoined at the start of the edge and then diverge.

The description just given in connection with FIGS. 5-6, 7A-7B, 8 and 9 can be transposed to the second half of the piston 13 and to the second transmission device 14b, not represented in these figures. Thus, one or more second openings are arranged in the second half of the piston, the frame 10 comprises one or more second islands, the second transmission device 14b is connected to one or more second islands by one or more second pivot hinges 16b.

Furthermore, by way of indicating and in no way limiting purposes, the first beams 1321 may extend through the second half of the piston 13, the second transmission device 14b may comprise a second transmission shaft 144b cut into several distinct portions, these portions advantageously being separated in pairs by a first beam 1321, the second transmission device 14b can be connected to the piston 13 by two second hinges, the cap 120 can comprise one or more second arms extending through the opening 121 to the second island(s) . . . .

Each second island is in an embodiment constructed in the same way as the first island 110 (for example in the manner described in connection with FIGS. 7A-7B).

It is remembered that the piston 13 (and especially its rigidifying structure 132), as well as the transmission devices 14a-14b, are advantageously symmetrical with respect to the plane P. The cap 120 is also advantageously symmetrical with respect to the plane P.

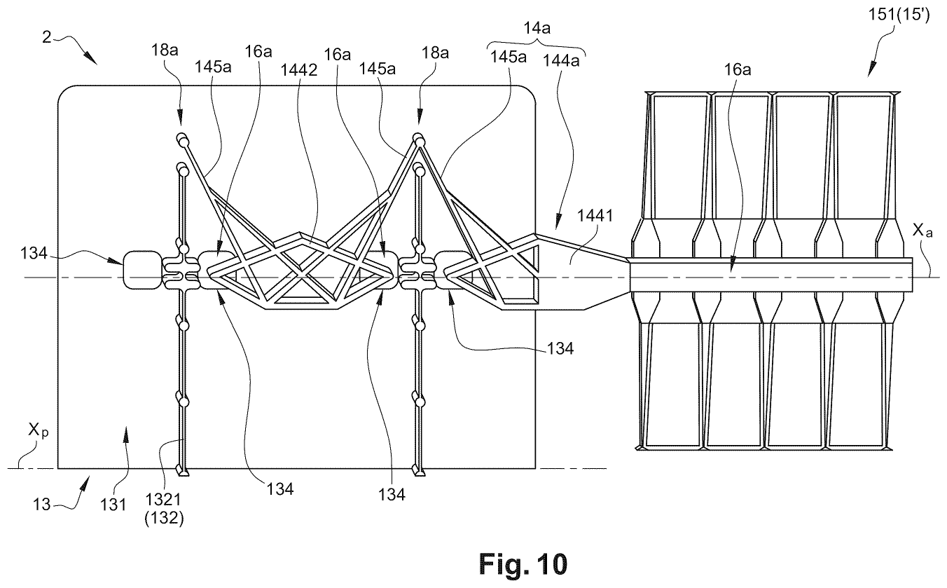

The electromechanical system 2 does not necessarily comprise the two movable electrodes 151-152 and the two transmission devices 154a-154b. It may comprise a single movable electrode and a single transmission device (see FIG. 10).

FIG. 10 represents a third embodiment in which the electromechanical system 2 comprises a single movable electrode 151 (for example of the type represented by FIG. 5) and a single transmission device 14a (for example of the type represented by FIG. 5).

The piston 13 is here rotatably movable about an axis Xp (and not translatable) by pivot hinges (not represented) separate from the (first) pivot hinges 16a. The rotational movement of the piston 13 (about the axis Xp) rotatably drives the transmission shaft 144a of the transmission device 14a (about its own axis Xa), via the transmission arms 145a, and the transmission shaft 144a moves the movable electrode 151 (here in rotation about the axis Xa).

The electromechanical system 2 is not limited to the embodiments described in connection with FIGS. 2 to 10 and many alternatives and modifications to the electromechanical system will become apparent to the person skilled in the art.

In particular, the transmission devices 14a-14b, and more specifically the transmission shafts 144a-144b, can assume other geometries. They can especially be continuous while being connected to islands in the piston zone.

The electromechanical system 2 of FIGS. 5-6 and 10 may include only two pivot hinges per transmission device 14a, 14b, for example one at the movable electrode 151, 152 and another at the opposite end of the transmission shaft 144a, 144b, this other pivot hinge being connected to an island in the zone of the piston 13.

The electromechanical system 2 has been described taking as an example a capacitive detection microphone comprising a piston 13 provided with a membrane 131 subjected on the one hand to atmospheric pressure and on the other hand to a reference pressure. The electromechanical system can, however, form other types of capacitive detection transducer, especially a loudspeaker (sound emitter) or an ultrasound emitter (which are electroacoustic transducers), or even a differential pressure sensor.

In the case of a differential pressure sensor, the first face of the membrane 131 is subjected to a first pressure (not necessarily atmospheric pressure) and the second face of the membrane 131 is subjected to a second pressure, different from the first pressure. The displacement of the membrane 131, under the effect of the pressure difference, is measured by the capacitive detector 15′. The membrane 131 of the piston is integral with the frame 10 so as to be sealed, and the rigidifying structure 132 for the piston is absent or reduced so as not to anchor it to the frame.

In the case of a loudspeaker or ultrasonic transmitter, capacitive actuator replaces the capacitive detector 15′. The capacitive actuator also comprises two movable electrodes and at least one counter-electrode per movable electrode. The movable electrodes are moved by an electrostatic force and this movement is transmitted by the transmission devices 14a, 14b to the piston 13. The movement of the membrane 131 of the piston 13 makes it possible to emit a sound (or ultrasound).

The second zone 12 may comprise two controlled atmosphere chambers, one enclosing the first movable electrode 151, the other enclosing the second movable electrode 152.

The first and second sealingly isolated zones 11-12 are not necessarily subjected to different pressures. The first zone 11 can also be an aggressive environment and the movable electrodes of the (detection or actuation) capacitor are placed in the second zone 12 to protect them from this aggressive environment (in addition to reducing viscous friction, and therefore acoustic noise).

The electromechanical system 2 may even be devoid of sealing device or seal between the first and second zones 11-12 (which amounts to considering only one zone). More particularly, the pivot hinges 16 located at the electrodes may be devoid of a sealed isolation element 161. Indeed, the torsion blades 162 may suffice for the rotation of the transmission device 14a, 14b and as elastic “anti-pull-in” device.

Expressions such as “comprise”, “include”, “incorporate”, “contain”, “is” and “have” are to be construed in a non-exclusive manner when interpreting the description and its associated claims, namely construed to allow for other items or components which are not explicitly defined also to be present. Reference to the singular is also to be construed in be a reference to the plural and vice versa.

The articles “a” and “an” may be employed in connection with various elements, components, compositions, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

As used herein in the specification and in the claims, the phrase “at least one”, in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified.

A person skilled in the art will readily appreciate that various features, elements, parameters disclosed in the description may be modified and that various embodiments disclosed may be combined without departing from the scope of the invention. For example, various aspects or embodiments of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in an embodiment may be combined in any manner with aspects described in other embodiments.

Having described above several aspects of at least one embodiment, it is to be appreciated various alterations, modifications, and improvements will readily occur to those skilled in the art. Such alterations, modifications, and improvements are intended to be aspects of this disclosure. Accordingly, the foregoing description and drawings are by way of example only.

1. An electromechanical system comprising:
a frame;
an element movable relative to the frame, the movable element comprising a membrane and a rigidifying structure for the membrane;
a capacitive measurement or actuation device;
a first movement transmission device for a movement between the movable element and the capacitive measurement or actuation device, the first transmission device being rotatably movable relative to the frame by a plurality of first pivot hinges;
wherein:
a first opening is arranged in the movable element;
the frame comprises a first island extending into the first opening; and
the first transmission device is connected to the first island via one of the first pivot hinges.

2. The system according to claim 1, wherein a portion of the first island forms a stop for limiting displacement of the movable element.

3. The system according to claim 2, wherein:
the rigidifying structure for the movable element comprises two fingers; and
the first island comprises a finger configured to bear against the membrane of the movable element between the two fingers of the rigidifying structure.

4. The system according to claim 1, wherein the first transmission device comprises:
a first transmission shaft having a first longitudinal axis of rotation;
at least one first transmission arm comprising a first end coupled to the movable element and a second end integral with the first transmission shaft.

5. The system according to claim 4, wherein the first transmission shaft comprises a first portion which extends to the capacitive measurement or actuation device and a second portion connected to the first island, the first and second portions of the first transmission shaft being distinct.

6. The system according to claim 5, comprising a first hinge between the movable element and the first transmission device and wherein the first transmission device comprises two first transmission arms converging towards the first hinge, one of the two first transmission arms extending from the first portion of the first transmission shaft and the other of the two first transmission arms extending from the second portion of the first transmission shaft.

7. The system according to claim 5, wherein:
the first transmission shaft is located on a first side of the membrane of the movable element;
the rigidifying structure for the movable element comprises a first beam located on the first side of the membrane; and
the first and second portions of the first transmission shaft are separated by the first beam.

8. The system according to claim 7, wherein the first beam extends in a direction perpendicular to the first longitudinal axis of rotation and has a length greater than or equal to 50% of the dimension of the movable element measured in said direction.

9. The system according to claim 7, wherein:
the rigidifying structure for the movable element comprises two first beams located on the first side of the membrane and extending in parallel to each other; and
the second portion of the first transmission shaft is located between the first two beams.

10. The system according to claim 7, wherein the rigidifying structure for the movable element further comprises a second beam located on a second opposite side of the membrane and superimposed on the first beam.

11. The system according to claim 7, wherein the rigidifying structure for the movable element further comprises ridges located on a second opposite side of the membrane and extending perpendicularly to the first beam.

12. The system according to claim 1, wherein the frame comprises a cap provided with an opening to provide access to the movable element and wherein the cap comprises a first arm extending through the opening to the first island.

13. The system according to claim 1, wherein:
several first openings are arranged in the movable element;
the frame comprises several first islands, each first island extending into one of the first openings; and
the first transmission device is connected to at least part of the first islands via part of the first pivot hinges.

14. The system according to claim 1, further comprising a second movement transmission device for a movement between the movable element and the capacitive measurement or actuation device, the second transmission device being rotatably movable relative to the frame by a plurality of second pivot hinges; and wherein:
a second opening is arranged in the movable element;
the frame comprises a second island extending into the second opening; and
the second movement transmission device is connected to the second island via one of the second pivot hinges.

15. The system according to claim 1, wherein the capacitive measurement or actuation device comprises:
a first electrode movable relative to the frame; and
at least one electrode fixed relative to the frame and separated from the first movable electrode by a first dielectric medium.

16. The system according to claim 15, wherein the movable element is in contact with a first zone and the first movable electrode is located in a second zone sealingly isolated from the first zone.

17. The system according to claim 15 wherein:
at least one of the first pivot hinges is located at the first movable electrode;
another of the first pivot hinges is located at one end of the first transmission device and connects the first transmission device to the first island.

18. The system according to claim 15, wherein the capacitive measurement or actuation device further comprises:
a second electrode movable relative to the frame; and
at least one additional electrode fixed relative to the frame and separated from the second movable electrode by a second dielectric medium.
